(19) United States
(12) Patent Application Publication
(10) Pub. No.: US 2024/0057316 A1
(43) Pub. Date: Feb. 15, 2024

(54) BURIED GATE STRUCTURE FOR DYNAMIC RANDOM ACCESS MEMORY AND METHOD FOR FORMING THE SAME

(71) Applicant: Winbond Electronics Corp., Taichung City (TW)

(72) Inventors: Yu-Ting CHEN, Taichung City (TW); Wei-Che CHANG, Taichung City (TW)

(21) Appl. No.: 18/447,851

(22) Filed: Aug. 10, 2023

(30) Foreign Application Priority Data
Aug. 10, 2022 (TW) 111129974

(51) Int. Cl. H10B 12/00

(52) U.S. Cl. CPC H10B 12/34; H10B 12/315; H10B 12/053

(57) ABSTRACT

A buried gate structure and a method for forming the same are provided. The structure includes first and second gate dielectric layers respectively formed on the surface of the lower portion and the surface of the upper portion of a gate trench of the semiconductor substrate. The structure includes a first gate electrode formed on the first gate dielectric layer. The structure includes an insulating cap layer formed on the first gate electrode to fill the remaining space of the gate trench. The first gate dielectric layer includes a negative capacitance dielectric material. The second gate dielectric layer includes a different dielectric material than the negative capacitance dielectric material. The interface between the first gate dielectric layer and the second gate dielectric layer is lower than the bottom surfaces of the source region and the drain region of the semiconductor substrate.

### CROSS REFERENCE TO RELATED APPLICATIONS

This application claims priority of Taiwan Patent Application No. 111129974, filed on Aug. 10, 2022, and entitled “BURIED GATE STRUCTURE AND METHOD FOR FORMING THE SAME AND DYNAMIC RANDOM ACCESS MEMORY STRUCTURE HAVING BURIED GATE STRUCTURE”, the entirety of which is incorporated by reference herein.

### BACKGROUND OF THE INVENTION

### Field of the Invention

The present invention relates to a semiconductor device and a method for forming the same, and in particular to a buried gate structure with a negative capacitance dielectric material and the method for forming the same, and a dynamic random access memory structure with a buried gate structure.

### Description of the Related Art

Dynamic random access memory (DRAM) is a volatile memory and is composed of multiple memory cells. More specifically, each memory cell is composed of a transistor and a capacitor, in which the capacitor is controlled by the transistor, and is selected through a word line and a bit line.

As the integration of semiconductor devices increases, DRAMs with buried word lines have been developed in recent years. However, as the size of DRAMs shrinks, gate induced drain leakage (GIDL) becomes more severe, which adversely affects write recovery time (tWR) and subthreshold swing (SS). As a result, DRAM performance is reduced in such ways as the DRAM being slower and the power consumption being increased.

### BRIEF SUMMARY OF THE INVENTION

Embodiments of the present invention provide a buried gate structure and a method for forming the same, which can decrease the write recovery time of a memory device and reduce the sub-threshold swing of a transistor, while avoiding the GIDL effect.

In some embodiments, a buried gate structure disposed in the gate trench of a semiconductor substrate is provided. The gate trench is formed between a source region and a drain region, and the buried gate structure includes a first gate dielectric layer formed on the surface of the lower portion of the gate trench. The first gate dielectric layer includes a negative capacitance dielectric material. The gate trench also includes a first gate electrode formed on the first gate dielectric layer and a second gate dielectric layer formed on the surface of the upper portion of gate trench. The second gate dielectric layer includes a different dielectric material than the negative capacitance dielectric material. The interface between the first gate dielectric layer and the second gate dielectric layer is lower than the bottom surfaces of the source region and the drain region. The buried gate structure further includes an insulating cap layer formed on the first gate electrode to fill the remaining space of the gate trench.

In some embodiments, a dynamic random access memory (DRAM) structure is provided. The DRAM structure includes a semiconductor substrate having a source region, a drain region, and a gate trench formed between the source region and the drain region. The DRAM structure also includes a buried gate structure as mentioned above, a bit line electrically connected to the source region or the drain region. The DRAM structure further includes a capacitor electrically connected to the other of the source region or the drain region.

In some embodiments, a method for forming a buried gate structure is provided. The method includes forming a gate trench in a semiconductor substrate and conformably forming a first gate dielectric layer on the surface of the lower portion of the gate trench. The first gate dielectric layer includes a negative capacitance dielectric material. The method also includes forming a first gate electrode on the first gate dielectric layer and conformably forming a second gate dielectric layer on the surface of the upper portion of the gate trench. The second gate dielectric layer includes a different dielectric material than the negative capacitance dielectric material. The interface between the first gate dielectric layer and the second gate dielectric layer is lower than the bottom surfaces of the source region and the drain region. The method further includes forming an insulating cap layer on the first gate electrode to fill the remaining space of the gate trench.

According to some embodiments, since a negative capacitance dielectric material is used as the gate dielectric layer of the buried gate structure, the on-state current (Ion) can be increased, so as to decrease the write recovery time of the memory device. Moreover, it is capable of reducing the sub-threshold swing of the transistor via the negative capacitance effect of the negative capacitance dielectric material. As a result, the operating speed of the memory device can be increased and the operating voltage of the memory device can be reduced, thereby improving the memory device performance. In addition, according to some embodiments, the ability of the gate dielectric layer to suppress the GIDL effect can be enhanced by using another different dielectric material than the negative capacitive material as the gate dielectric layer of the buried gate structure. As a result, the yield and reliability of the memory device can be effectively improved.

### BRIEF DESCRIPTION OF THE DRAWINGS

The present disclosure can be more fully understood by reading the subsequent detailed description and examples with references made to the accompanying drawings, wherein:

FIGS. 1A to 1H illustrate cross-sectional views of various stages of forming a buried gate structure according to some embodiments.

FIG. 1I illustrates a cross-sectional view of a dynamic random access memory structure with a buried gate structure according to some embodiments.

FIGS. 2A to 2C illustrate cross-sectional views of various stages of forming a buried gate structure according to some embodiments.

FIGS. 3A to 3E illustrate cross-sectional views of various stages of forming a buried gate structure according to some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

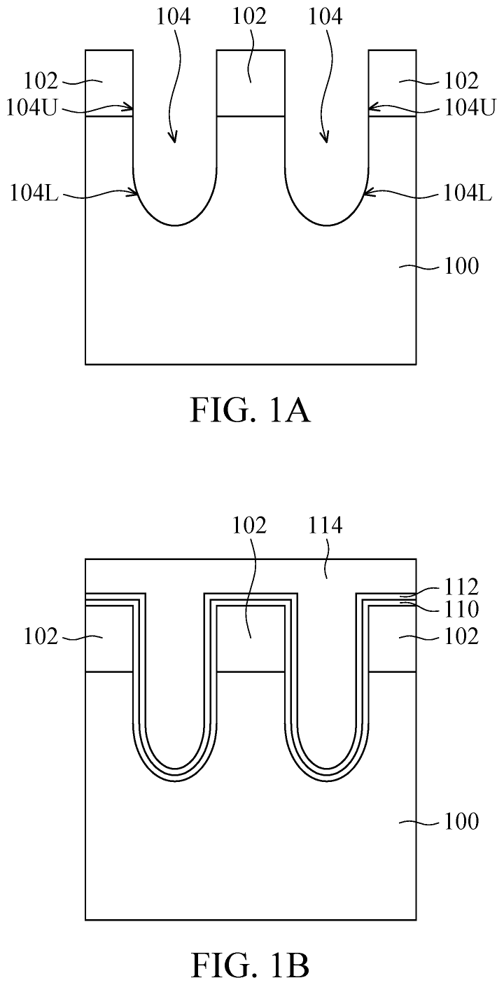

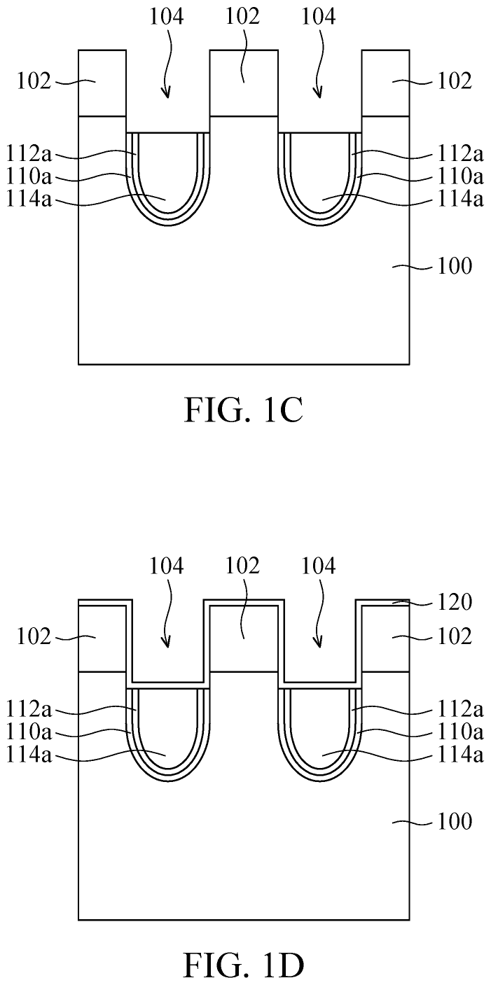

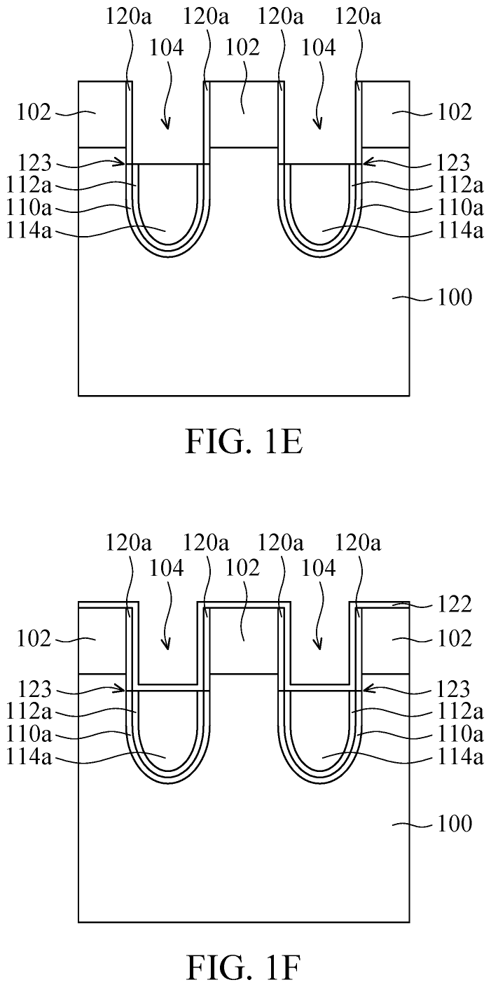

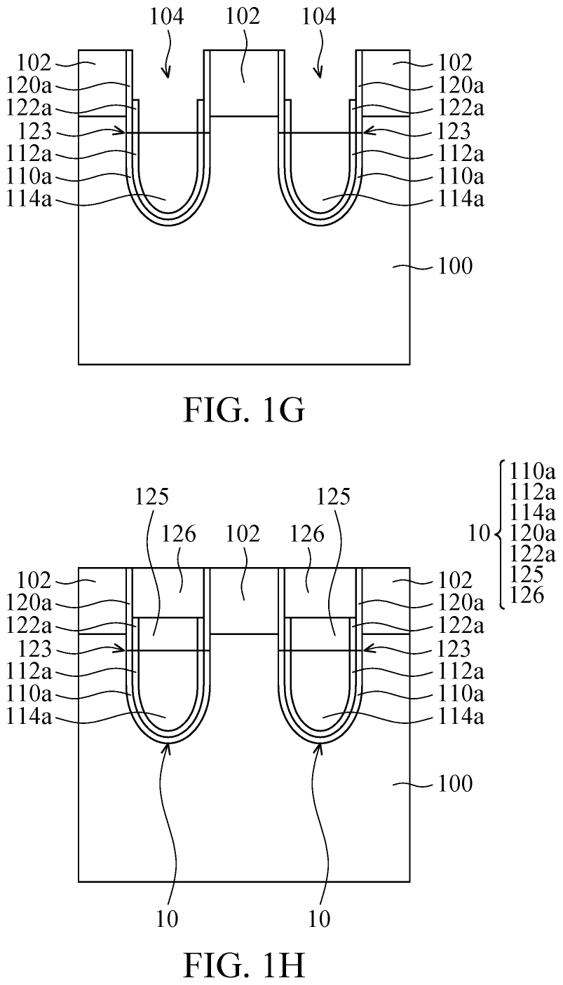

FIGS. 1A to 1I illustrate cross-sectional views of various stages of forming a buried gate structure according to some embodiments. Referring to FIG. 1A, gate trenches 104 are formed in a semiconductor substrate 100 by a patterning process (e.g., lithography and etching processes). Afterwards, source/drain regions 102 may be formed in the semiconductor substrate 100 on both sides of each gate trench 104 by using ion implantation or other conventional techniques. In some embodiments, the semiconductor substrate 100 may be a silicon wafer. In some embodiments, the semiconductor substrate 100 may be a bulk semiconductor, a semiconductor-on-insulator (SOI) substrate, a multi-layer substrate, or a gradient substrate. In some other embodiments, the semiconductor substrate 100 is made of elementary semiconductor (e.g., silicon, germanium), compound semiconductor (e.g., silicon carbide, gallium arsenide, gallium phosphide, indium phosphide, indium arsenide and/or indium antimonide), alloy semiconductor (e.g., SiGe, GaAsP, AlInAs, AlGaAs, GaInAs, GaInP, and/or GaInAsP or combinations thereof). The conductivity type of the semiconductor substrate 100 may be N-type or P-type, depending on the conductivity type of the subsequently formed transistor structure.

Referring to FIGS. 1B to 1C, in some embodiments, a first gate dielectric material 110a, a first barrier layer 112a, and a first gate electrode 114a are successively formed on the surface of the lower portion 104L (indicated in FIG. 1A) of each gate trench 104, so that the top surface of the first gate dielectric material 110a is lower than the bottom surfaces of the source/drain regions 102. For example, as shown in FIG. 1B, a gate dielectric material 110 and a barrier material 112 are successively and conformally formed on the semiconductor substrate 100 having gate trenches 104. Afterwards, a gate dielectric material 114 fully filling the gate trenches 104 are formed on the barrier material 112. In some embodiments, the gate dielectric material 110 includes a negative capacitance dielectric material, for example, hafnium zirconium oxide (HfxZr₁₋ₓO₂, HZO), doped hafnium oxide (doped HfO₂), doped zirconium oxide (doped ZrO₂), potassium dihydrogen phosphate (KH₂PO₄), barium titanate (BaTiO₃, BTO), lead zirconate titanate (Pb[ZrₓTi₁₋ₓ]O₂, PZT), bismuth ferrite (BiFeO₃, BFO), strontium bismuth tantalate (SrBi₂Ta₂O₉, SBT), aluminum scandium nitride (AlScN), or combinations thereof. Moreover, the gate dielectric material 110 and the barrier material 112 can be formed by a chemical vapor deposition (CVD) process, an atomic layer deposition (ALD) process, or another deposition process. In some embodiments, the barrier material 112 may include titanium (Ti), titanium nitride (TiN), tantalum (Ta), tantalum nitride (TaN), or the like.

In some embodiments, the gate electrode material 114 includes a metal material, such as aluminum, copper, titanium, tungsten, the like, alloys thereof, or combinations thereof. Moreover, the gate electrode material 114 is formed by a CVD process, a sputtering process, an electron beam (E-beam) evaporation process, an ALD process, or any other suitable deposition processes.

Referring to FIG. 1C, in some embodiments, the gate electrode material 114, the barrier material 112, and the gate dielectric material 110 are etched back to expose the top surface of each source/drain region 102 and the upper portion 104U of each gate trench 104 (indicated in FIG. 1A), and form the first gate electrode 114a, the first barrier layer 112a, and the first gate dielectric layer 110a. The gate electrode material 114, the barrier material 112, and the gate dielectric material 110 may be removed by a planarization process (e.g., a chemical mechanical polishing (CMP) process) and/or an etching process (e.g., a dry or wet etching process).

In some embodiments, the top surfaces of the first gate electrode 114a, the first barrier layer 112a, and the first gate dielectric layer 110a are lower than the bottom surfaces of the source/drain regions 102. In an embodiment, the top surface of the first gate electrode 114a is level with the top surfaces of the first gate dielectric layer 110a and the first barrier layer 112a.

Referring to FIG. 1D, in some embodiments, a gate dielectric material 120 is blanketly and conformably formed to cover the top surfaces of the source/drain regions 102, the upper portion 104U of each gate trench 104, the top surface of the first gate electrode 114a, and the top surfaces of the first gate dielectric layer 110a and the first barrier layer 112a. In some embodiments, the gate dielectric material 120 includes a different dielectric material than the gate dielectric material 110, such as silicon oxide, silicon nitride, a low-k dielectric material (e.g., a material having a dielectric constant (k) less than that of silicon oxide), or a combination of the above. Moreover, the gate dielectric material 110 may be formed by a chemical vapor deposition (CVD) process, an atomic layer deposition (ALD) process, or any other suitable deposition process.

Referring to FIG. 1E, in some embodiments, the gate dielectric material 120 is etched to expose the top surface of the first gate electrode 114a, and a second gate dielectric layer 120a is formed on the surface of the upper portion 104U of each gate trench 104. As a result, the second gate dielectric layer 120a is formed on the first gate dielectric layer 110a. Therefore, an interface 123 is formed between the second gate dielectric layer 120a and the underlying first gate dielectric layer 110a. In some embodiments, the interface 123 is lower than the bottom surfaces of the source/drain regions 102. In some embodiments, the interface 123 is not higher than the top surface of the first gate electrode 114a. For example, the interface 123 may be substantially level with the top surface of the first gate electrode 114a.

Referring to FIG. 1F, a barrier material 122 is blanketly and conformally formed to cover the top surfaces of the source/drain regions 102 and the top surfaces of the second gate dielectric layer 120a and the first gate electrode 114a. In some embodiments, the material and formation method of the barrier material 122 are the same as or similar to the material and formation method of the barrier material 112.

Referring to FIG. 1G, the barrier material 122 is patterned to form a second barrier layer 122a on the first barrier layer 112a. For example, the barrier material 122 is etched back to expose a portion of the second gate dielectric layer 120a. The top surface of the second barrier layer 122a is higher than the top surface of the first gate dielectric layer 110a and lower than the top surface of the second gate dielectric layer 120a.

Referring to FIG. 1H, a second gate electrode 125 is formed above the first gate electrode 114a, so that the top surface of the second gate electrode 125 is higher than the interface 123. In some embodiments, the top surface of the second gate electrode 125 is substantially level with the top surface of the second barrier layer 122a. Moreover, the material and formation method of the second gate electrode 125 are the same as or similar to the material and formation method of the first gate electrode 114a. In some embodiments, the buried gate structure can be used as the word line structure of the memory device.

Next, an insulating cap layer 126 is formed on the top surface of the second gate electrode 125 to fill the remaining space of the gate trench 104, thereby forming the buried gate structure 10. In some embodiments, the insulating capping layer 126 includes a different dielectric material than those of the first gate dielectric layer 110a and the second gate dielectric layer 120a, such as silicon nitride or other suitable dielectric materials. In some embodiments, the top surface of insulating cap layer 126 is substantially level with the top surfaces of source/drain regions 102

Referring to FIG. 1I, in some embodiments, bit lines 201 and capacitors 202 can be formed over the structure shown in FIG. 1H using generally well-known semiconductor technologies to form a dynamic random access memory structure 50. In the dynamic random access memory structure 50, on opposite sides of each buried gate structure, the bit line 201 is electrically connected to the source/drain region 102 on one side, and the capacitor 202 is electrically connected to the source/drain area 102 on the other side.

According to the embodiments, the negative capacitance dielectric material is used as part of the gate dielectric layer, so that the on-state current can be increased. As a result, the write recovery time of the memory device can be decreased. Moreover, the negative capacitance effect also reduces the subthreshold swing of the transistor, thereby increasing the operating speed of the memory device and reducing its operating voltage (i.e., reducing power consumption). That is, the buried gate structure with negative capacitance dielectric material of the present embodiment can improve memory device performance. In addition, according to some embodiments, the gate dielectric layer of the buried gate structure includes a different dielectric material than the negative capacitance material to improve the ability to suppress the gate induced drain current (GIDL) effect, thereby improving the yield and reliability of the memory device.

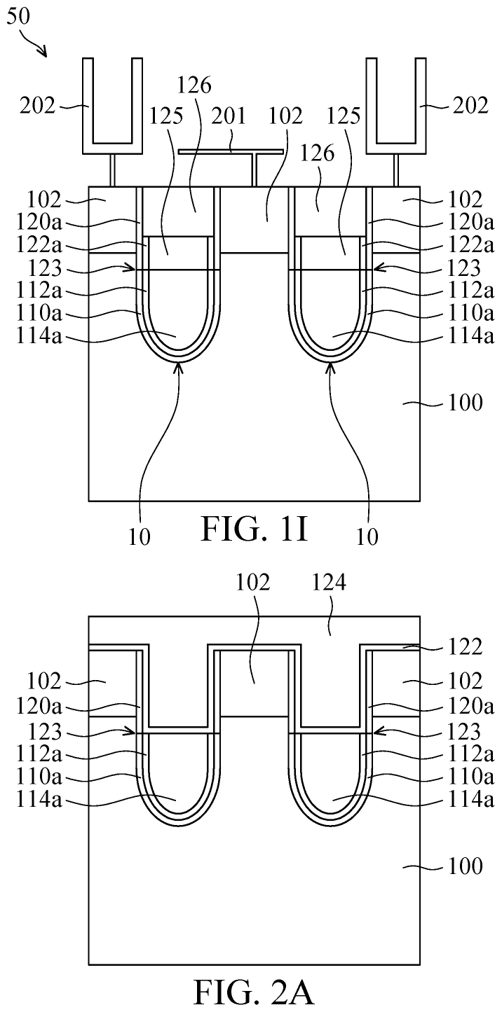

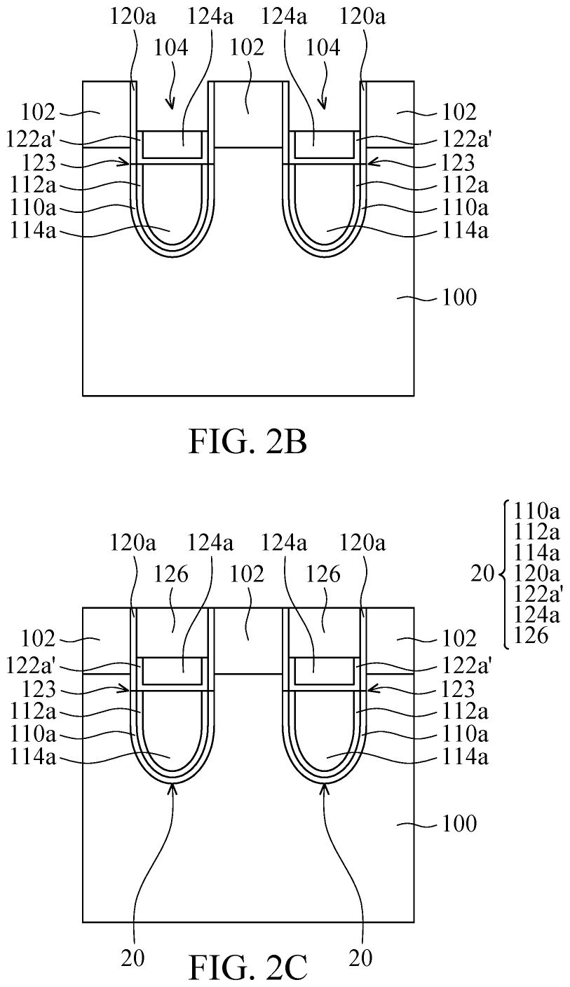

FIGS. 2A to 2C illustrate cross-sectional views of various stages of forming a buried gate structure 20 according to some embodiments. Herein, elements in FIGS. 2A to 2C that are the same as those of the buried gate structure 10 in FIGS. 1A to 1H are labeled with the same reference numbers as in FIGS. 1A to 1H and are not described again for brevity. Referring to FIG. 2A, in some embodiments, the structure as shown in FIG. 1F is provided. Thereafter, a gate electrode material 124 is formed on the barrier material 122 and fills the remaining space of gate trenches 104. In some embodiments, the gate electrode material 124 may include a metal material, such as aluminum, copper, titanium, tungsten, the like, an alloy thereof, or a combination thereof. Moreover, the gate electrode material 124 is formed by a chemical vapor deposition (CVD) process, a sputtering process, an electron beam (E-beam) evaporation process, an atomic layer deposition (ALD) process, or any other suitable deposition processes.

Referring to FIG. 2B, in some embodiments, the gate electrode material 124 and the barrier material 122 are etched simultaneously or separately to expose the top surface of the source/drain regions 102 and a partial second gate dielectric layer 120a, and form a second gate electrode 124a and a second barrier layer 122a′. For example, the gate electrode material 124 and the barrier material 122 may be etched back by one or more planarization processes (e.g., CMP processes) and/or one or more etching processes (e.g., dry or wet etching processes). In some embodiments, the top surfaces of the second gate electrode 124a and the second barrier layer 122a′ are higher than the bottom surfaces of the source/drain regions 102. In the embodiment, the second barrier layer 122a′ is formed on the first barrier layer 112a and the first gate electrode 114a, so that the second gate electrode 124a is separated from the first gate electrode 114a by the second barrier layer 122a′. The top surface of the second gate electrode 124a may be substantially level with the top surface of the second barrier layer 122a′ and higher than the interface between the first gate dielectric layer 110a and the second gate dielectric layer 120a.

Referring to FIG. 2C, in some embodiments, the insulating cap layer 126 is formed on the second gate electrode 124a by the method as illustrated in FIG. 1H to fill the remaining space of the gate trench 104, thereby forming the buried gate structure 20.

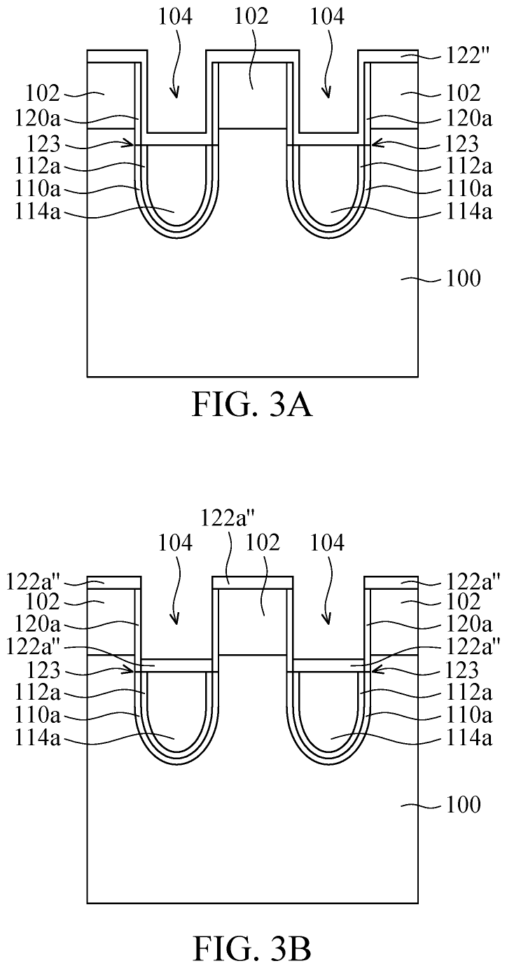

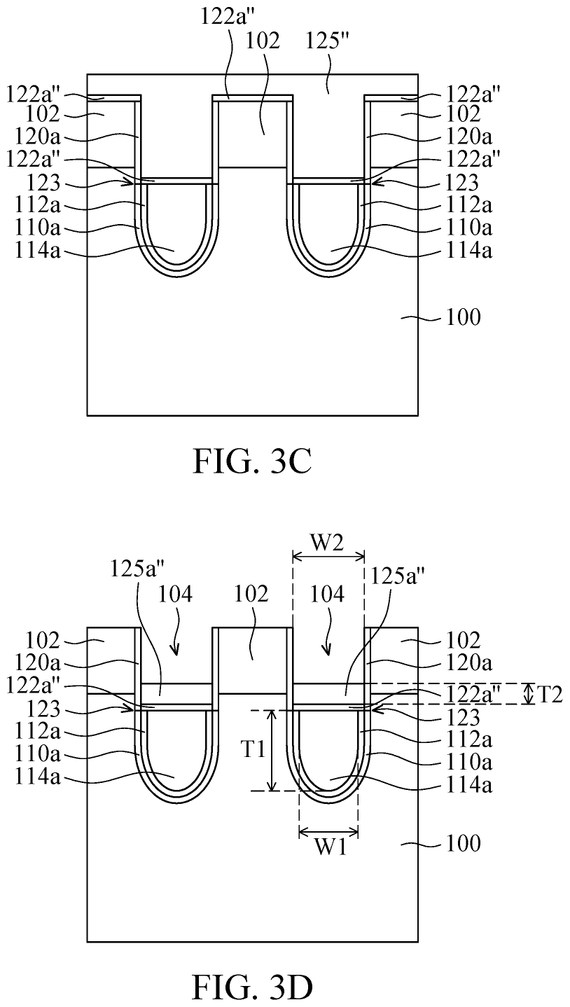

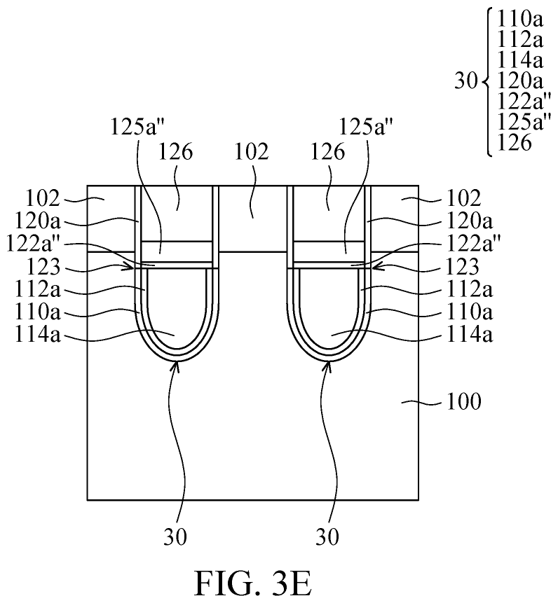

FIGS. 3A to 3E illustrate cross-sectional views of various stages of forming a buried gate structure 30 according to some embodiments. Herein, elements in FIGS. 2A to 2C that are the same as those of the buried gate structure 10 in FIGS. 1A to 1H are labeled with the same reference numbers as in FIGS. 1A to 1H and are not described again for brevity. Referring to FIG. 3A, in some embodiments, a structure as shown in FIG. 1E is provided. Thereafter, a barrier material 122″ is formed on the top surface of the source/drain regions 102, the second gate dielectric layer 120a, the top surface of the first gate electrode 114a, and the top surface of the first barrier layer 112a. In some embodiments, the material of the barrier material 122″ is the same as or similar to the material of the barrier material 122 as shown in FIG. 1F. However, unlike the barrier material 122, the barrier material 122″ covering the top surfaces of the source/drain regions 102 and the first gate electrode 114a has a thickness greater than the barrier material 122″ covering the second gate dielectric layer 120a.

Referring to FIG. 3B, the barrier material 122″ is thinned. For example, the barrier material 122 is isotropically etched to remove the portion of the barrier material 122″ covering the second gate dielectric layer 120a, so as to expose the second gate dielectric layer 120a. The remaining barrier material 122″ forms a second barrier layer 122a″ to cover the source/drain regions 102, the first barrier layer 112a, and the first gate electrode 114a. The second barrier layer 122a″ formed on the top surface of the first gate electrode 114a has a top surface that is lower than the bottom surface of the source/drain regions 102.

Referring to FIG. 3C, in some embodiments, a gate electrode material 125″ is formed on the top surface of the second barrier layer 122a″ and fills the remaining space of the gate trench 104. In some embodiments, the gate electrode material 125″ includes a polysilicon material.

Referring to FIG. 3D, in some embodiments, the gate electrode material 125″ and the second barrier layer 122a″ that is on the top surface of the source/drain regions 102 are etched simultaneously or separately to expose the top surface of the source/drain regions 102 and a portion of the second gate dielectric layer 120a, and to form a second gate electrode 125a″. In some embodiments, the top surface of the second gate electrode 125a″ is higher than the interface 123 between the first gate dielectric layer 110a and the second gate dielectric layer 120a and the bottom surfaces of the source/drain regions 102. In some embodiments, unlike the second barrier layer 122a shown in FIG. 1G, the second barrier layer 122a″ is formed between the second gate electrode 125a″ and the first gate electrode 114a, so that the second gate electrode 125a″ is separated from the first gate electrode 114a by the second barrier layer 122a″. Further, the sidewall of the second gate electrode 125a″ is in direct contact with the second gate dielectric layer 120a. In addition, the maximum width W2 of the second gate electrode 125a″ is greater than the maximum width W1 of the first gate electrode 114a, and the maximum thickness T2 of the second gate electrode 125a″ is less than the maximum thickness T1 of the first gate electrode 114a. According to this embodiment, the gate electrode of the buried gate structure includes two different gate electrode materials (e.g., metal material and polysilicon material), so that the work function of the gate electrode can be further adjusted to improve the GIDL effect.

Referring to FIG. 3E, in some embodiments, an insulating cap layer 126 is formed on the second gate electrode 125a″ by the method as illustrated in FIG. 1H to fill the remaining space of the gate trench 104, thereby forming the buried gate structure 30.

According to the above embodiment, the memory device uses a composite dielectric material including a negative capacitive material and another different dielectric material than the negative capacitive material as the gate dielectric layer of the buried gate structure. Accordingly, the write recovery time of the memory device can be decreased, the operation speed can be increased, the operation voltage can be reduced, and the GIDL effect can be suppressed, thereby improving the performance, yield, and reliability of the memory device. In addition, by using two different gate electrode materials (e.g., metal material and polysilicon material) as the gate electrode of the buried gate structure, the work function of the gate electrode can be adjusted to improve the GIDL effect further.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A buried gate structure, disposed in a gate trench in a semiconductor substrate and between a source region and a drain region, comprising:
a first gate dielectric layer formed on a surface of a lower portion of the gate trench, wherein the first gate dielectric layer comprises a negative capacitance dielectric material;
a first gate electrode formed on the first gate electrode layer;
a second gate dielectric layer formed on a surface of an upper portion of the gate trench, wherein the second gate dielectric layer comprises a different dielectric material than the negative capacitance dielectric material, and wherein an interface between the first gate dielectric layer and the second gate dielectric layer is lower than a bottom surface of the source region and the drain region; and
an insulating cap layer formed on the first gate electrode to fill a remaining space of the gate trench.

2. The buried gate structure as claimed in claim 1, wherein the interface is not higher than a top surface of the first gate electrode.

3. The buried gate structure as claimed in claim 1, further comprising:
a barrier layer formed between the first gate electrode and the first gate dielectric layer; and
a second gate electrode formed between the first gate electrode and the insulating cap layer, wherein the interface is not higher than a bottom surface of the second gate electrode.

4. The buried gate structure as claimed in claim 1, wherein the negative capacitance dielectric material comprises hafnium zirconium oxide, doped hafnium oxide, doped zirconium oxide, potassium dihydrogen phosphate, barium titanate, lead zirconate titanate, bismuth ferrite, strontium bismuth tantalate, aluminum scandium nitride, or a combination thereof.

5. The buried gate structure as claimed in claim 1, wherein the dielectric material comprises silicon oxide, silicon oxynitride, low-k dielectric material or a combination thereof.

6. The buried gate structure as claimed in claim 1, further comprising a second gate electrode formed between the first gate electrode and the insulating cap layer, wherein the interface is lower than a bottom surface of the second gate electrode.

7. The buried gate structure as claimed in claim 6, further comprising:
a first barrier layer formed between the first gate electrode and the first gate dielectric layer; and
a second barrier layer formed between the second gate electrode and the second gate dielectric layer, wherein the first gate electrode and the second gate electrode comprise metal materials.

8. The buried gate structure as claimed in claim 6, further comprising:
a first barrier layer formed between the first gate electrode and the first gate dielectric layer; and
a second barrier layer formed between the first gate electrode and the second gate electrode layer, wherein the first gate electrode comprises a metal material and the second gate electrode comprises a polysilicon material, and wherein a sidewall of the second gate electrode is in direct contact with the second gate dielectric layer.

9. The buried gate structure as claimed in claim 6, wherein a maximum width of the second gate electrode is greater than a maximum width of the first gate electrode, and a maximum thickness of the second gate electrode is less than a maximum thickness of the first gate electrode.

10. A dynamic random access memory structure, comprising:
a semiconductor substrate having a source region, a drain region and a gate trench between the source region and the drain region;
a buried gate structure as claimed in claim 1;
a bit line electrically connected to the source region or the drain region; and
a capacitor electrically connected to the other of the source region or the drain region.

11. A method for forming a buried gate structure, comprising:
forming a gate trench in a semiconductor substrate;
conformally forming a first gate dielectric layer on a surface of a lower portion of the gate trench, wherein the first gate dielectric layer comprises a negative capacitance dielectric material;
forming a first gate electrode on the first gate dielectric layer;
conformally forming a second gate dielectric layer on a surface of an upper portion of the gate trench, wherein the second gate dielectric layer comprises a different dielectric material than the negative capacitance dielectric material, and an interface between the first gate dielectric layer and the second gate dielectric layer is lower than bottom surfaces of the source region and the drain region; and
forming an insulating cap layer on the first gate electrode to fill a remaining space of the gate trench.

12. The method as claimed in claim 11, wherein the interface is not higher than a top surface of the first gate electrode.

13. The method as claimed in claim 12, further comprising:
forming a second gate electrode on the first gate electrode after forming the second gate dielectric layer and before forming the insulating cap layer, wherein the interface is not higher than a bottom surface of the second gate electrode.

14. The method as claimed in claim 13, further comprising:
forming a first barrier layer on the first gate dielectric layer before forming the first gate electrode; and
forming a second barrier layer on the first barrier layer after forming the second gate dielectric layer and before forming the second gate electrode.

15. The method as claimed in claim 11, wherein the negative capacitance dielectric material comprises: hafnium zirconium oxide, doped hafnium oxide, doped zirconium oxide, potassium dihydrogen phosphate, barium titanate, lead zirconate titanate, bismuth ferrite, strontium bismuth tantalate, aluminum scandium nitride, or a combination thereof.

16. The method as claimed in claim 11, wherein the dielectric material comprises silicon oxide, silicon oxynitride, low-k dielectric material or a combination thereof.

17. The method as claimed in claim 11, further comprising:
forming a second gate electrode on the first gate electrode after forming the second gate dielectric layer and before forming the insulating cap layer, wherein the interface is lower than a bottom surface of the second gate electrode.

18. The method as claimed in claim 17, further comprising:
conformally forming a first barrier layer on the first gate dielectric layer before forming the first gate electrode; and
conformally forming a second barrier layer on the second gate dielectric layer and the first gate electrode before forming the second gate electrode, wherein the first gate electrode and the second gate electrode comprise metal materials.

19. The method as claimed in claim 17, further comprising:
conformally forming a first barrier layer on the first gate dielectric layer before forming the first gate electrode; and
conformally forming a second barrier layer to cover a top surface of the first gate electrode before forming the second gate electrode,
wherein the first gate electrode comprises a metal material and the second gate electrode comprises a polysilicon material, and wherein a sidewall of the second gate electrode is in direct contact with the second gate dielectric layer.

20. The method as claimed in claim 17, wherein a maximum width of the second gate electrode is greater than a maximum width of the first gate electrode, and a maximum thickness of the second gate electrode is less than a maximum thickness of the first gate electrode.
